(19) United States
(12) Patent Application Publication
(10) Pub. No.: US 2009/0050975 A1
(43) Pub. Date: Feb. 26, 2009

(54) Active Silicon Interconnect in Merged Finfet Process

(76) Inventors: Andres Bryant, Burlington, VT (US); Thomas Ludwig, Sindelfingen (DE); Edward J. Nowak, Essex Junction, VT (US)

Correspondence Address: FREDERICK W. GIBB, III;Gibb Intellectual Property Law Firm, LLC, 2568-A RIVA ROAD, SUITE 304, ANNAPOLIS, MD, 21401, US

(21) Appl. No.: 11/842,194

(22) Filed: Aug. 21, 2007

(51) Int. Cl. H01L 29/94

(52) U.S. Cl. 257/369; 257/E29.345

(57) ABSTRACT

Dummy fins are positioned between source and drain regions of adjacent complementary multi-gate fin-type field effect transistors (MUGFETS) prior to selective silicon growth and silicidation. The dummy fins are parallel to, have the same thickness as, and have a smaller length than the fins within the MUGFETs. Further, the source regions of a first MUGFET, the drain regions of a second MUGFET, and the dummy fins are positioned along a single straight linear path, such that the single straight linear path crosses all of the source regions of the first MUGFET, the drain regions of the second MUGFET, and the dummy fins. Because the dummy fins comprise silicon, the dummy fins enhance the ability to selectively grow silicon within the source/drain connection silicide region. Then, after the source/drain connection silicide region is silicided, a consistently formed and reliable electrical connection is made between the source regions of one transistor and the drain regions of the other transistor to properly connect a CMOS structure.

### BACKGROUND AND SUMMARY

The embodiments of the invention generally relate to complementary metal oxide semiconductor (CMOS) devices and more particularly to multi-gate, fin-type field effect transistor (MUGFET) CMOS devices that use dummy fins in the region that joins source and drain regions of the complementary transistors.

Recent advances in integrated circuit technology has produced novel structures such as MUGFET devices. See U.S. Patent Publications 20070131972 and 20070117311 incorporated herein by reference, for a complete discussion of MUGFET devices. However, difficulties have arisen when forming connections between complementary MUGFET devices used in CMOS structures. For example, in such structures, only fin shapes can be patterned and, thus, active silicon level (RX) interconnects are no longer possible. This can lead to decreased circuit density, and hence, increased cost.

Therefore, the present disclosure provides an apparatus that has a first multi-gate, fin-type field effect transistor (MUGFET) adjacent a second MUGFET. Each of the first MUGFET and the second MUGFET comprise multiple fins and each of the fins comprises a doped channel region. Doped source and doped drain regions of the fin are on opposite sides of the each of the channel regions.

The embodiments herein use a source/drain connecting silicide region to join the source regions of the first MUGFET to the drain regions of the second MUGFET. The first MUGFET comprises a complementary type of transistor to the second MUGFET. For example, one transistor is N-type and the other is P-type. Thus, the combination of the first MUGFET and the second MUGFET forms a complementary metal oxide semiconductor (CMOS) device.

One distinguishing feature of embodiments herein is dummy fins (that can be undoped, or be doped similarly to the source and drain regions, but that lack a channel region) that are positioned within the source/drain connecting silicide region. The dummy fins are parallel to, have the same thickness and pitch as, and have a smaller length than the fins within the first MUGFET and the second MUGFET. Further, the source regions of the first MUGFET, the drain regions of the second MUGFET, and the dummy fins are positioned along a single straight linear path, such that the single straight linear path crosses all of the source regions of the first MUGFET, the drain regions of the second MUGFET, and the dummy fins.

During selective silicon growth, silicon grows faster in regions where silicon already exists, as opposed to non-silicon regions that can comprise oxides, nitrides, etc. Because the dummy fins comprise silicon, the dummy fins enhance the ability to selectively grow silicon within the source/drain connection silicide region. Then, after the source/drain connection silicide region is silicided, a consistently formed and reliable electrical connection is made between the source regions of one transistor and the drain regions of another transistor to properly connect the CMOS structure.

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a schematic top-view diagram of a multi-gate fin-type transistor structure; and

FIG. 2 is a schematic top-view diagram of a multi-gate fin-type transistor structure.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

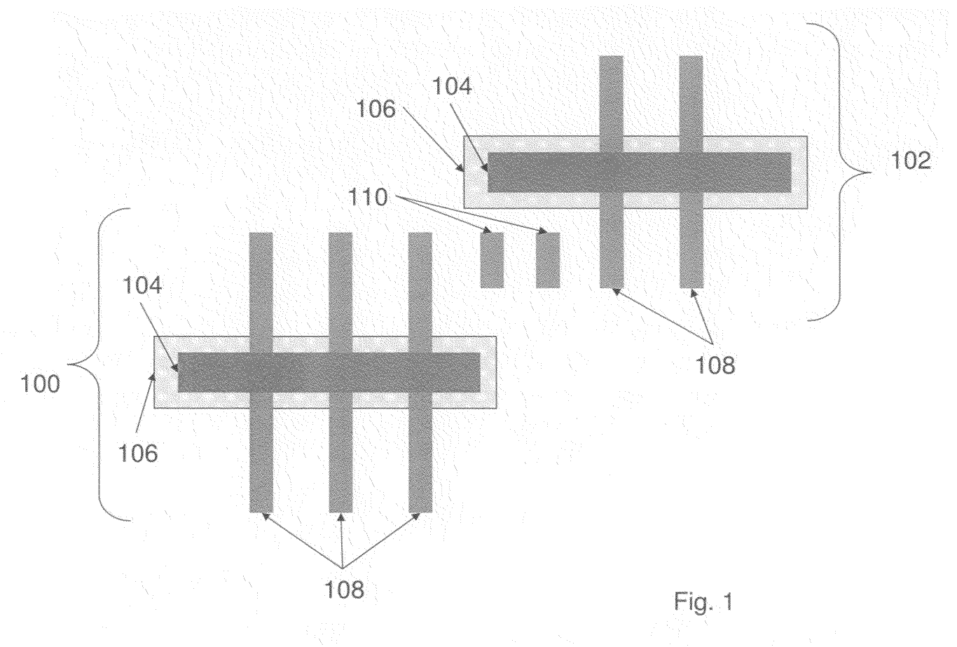

As mentioned above, difficulties have arisen when forming connections between complementary MUGFET devices used in CMOS structures. Therefore, as shown in FIG. 1, the present disclosure provides an apparatus that has a first multi-gate, fin-type field effect transistor (MUGFET) 100 adjacent a second MUGFET 102. Each of the first MUGFET 100 and the second MUGFET 102 comprise multiple silicon fins 108, a gate 104, and a spacer or insulator 106. Each of the fins 108 comprises a doped channel region beneath the gate 104. Each of the fins 108 also has a doped source region and a doped drain region on opposite sides of the each of the channel regions that are not covered by the gate 108. These aspects of the structure are known and are described in, for example, the previously mentioned U.S. Patent Publications 2007/0131972 and 2007/0117311, and a detailed discussion of such teachings is omitted herefrom to focus the reader on the salient portions of the invention.

One distinguishing feature of embodiments herein are dummy fins 110 that can be undoped, or can be doped similarly to the source and drain regions, but that lack a channel region. The dummy fins 110 are formed in the same patterning/formation process used to form the MUGFET fins 108 and are therefore made at the same time, made of the same material, have the same height and thickness, but can be shorter in length to comply with spacing requirements between transistors 100, 102. Thus, as shown in FIG. 1, the dummy fins 110 are parallel to, have the same pitch and thickness as, and have a smaller length than the fins 108 within the first MUGFET 100 and the second MUGFET 102.

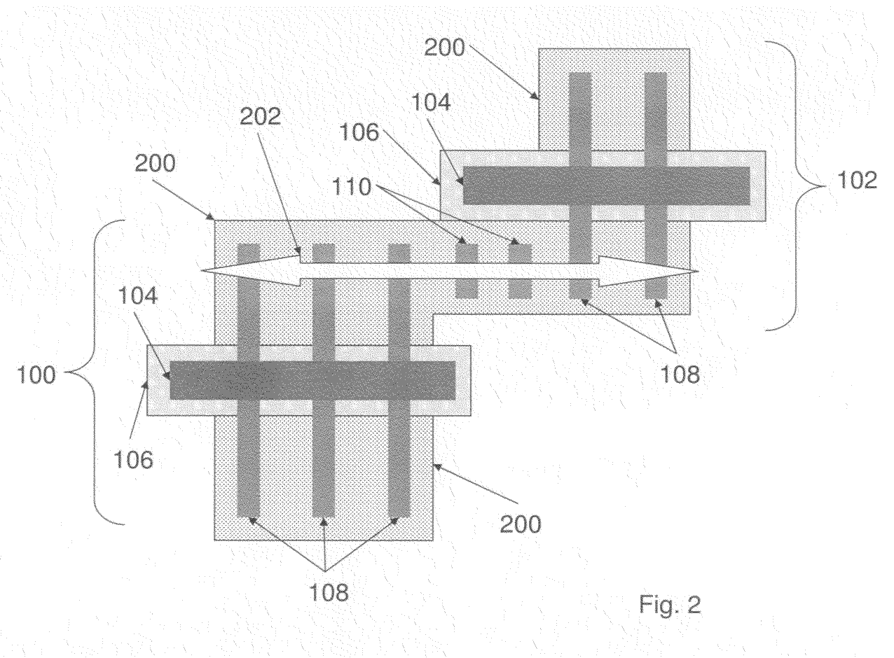

The structure shown in FIG. 1 is subjected to any well-known selective silicon growth process followed by any well-known silicidation process to result in the structure shown in FIG. 2. For example, such selective silicon growth and siliciding processes are discussed in length in U.S. Patent Publications 2007/0048980 and 2003/0219971 (incorporated herein by reference) and a detailed discussion of such teachings is omitted herefrom to focus the reader on the salient portions of the invention. The silicided silicon growth regions are shown as items 200 in FIG. 2.

During the selective silicon growth, silicon grows faster in regions where silicon already exists, as opposed to non-silicon regions that can comprise oxides, nitrides, etc. Because the dummy fins comprise silicon, the dummy fins 110 enhance the ability to selectively grow silicon within a source/drain connection silicide region 202. Then, after the source/drain connection silicide region 202 is silicided, a consistently formed and reliable electrical connection is made between the source regions of one transistor and the drain regions of the other transistor to properly connect the CMOS structure along the source/drain connection silicide region 202.

The embodiments herein use the source/drain connecting silicide region 202 to join the source regions of the first MUGFET 100 to the drain regions of the second MUGFET 102. Thus, the dummy fins 110 are positioned within the source/drain connecting silicide region 202 in the final manufactured structure. Further, the source regions of the first MUGFET 100, the drain regions of the second MUGFET 102, and the dummy fins 110 are positioned along a single straight linear path (represented by arrow 202), such that the single straight linear path 202 crosses all of the source regions of the first MUGFET 100, the drain regions of the second MUGFET 102, and the dummy fins 110.

As mentioned above, the first MUGFET 100 comprises a complementary type of transistor to the second MUGFET 102. For example, one transistor could be N-type and the other could be P-type. Thus, the combination of the first MUGFET 100 and the second MUGFET 102 forms a complementary metal oxide semiconductor (CMOS) device.

Once again, because the dummy fins comprise silicon, the dummy fins enhance the ability to selectively grow silicon within the source/drain connection silicide region. Then, after the source/drain connection silicide region is silicided, a consistently formed and reliable electrical connection is made between the source regions of one transistor and the drain regions of another transistor to properly connect the CMOS structure. Thus, the foregoing explains a method of constructing active silicon interconnects by introduction of dummy fins 110 between transistors, allowing the selective silicon, and subsequently, the metal silicide, to bridge and interconnect transistors.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of embodiments, those skilled in the art will recognize that the embodiments of the invention can be practiced with modification within the spirit and scope of the appended claims.

What is claimed is:

1. An apparatus comprising:
a first multi-gate, fin-type field effect transistor (MUGFET) adjacent a second MUGFET, wherein each of said first MUGFET and said second MUGFET comprise multiple fins, and wherein each of said fins comprises a channel region, and a source region and a drain region on opposite sides of said channel region;
a source/drain connecting silicide region joining source regions of said first MUGFET to drain regions of said second MUGFET; and
dummy fins lacking said channel region and being positioned within said source/drain connecting silicide region.

2. The apparatus according to claim 1, wherein said first MUGFET is comprises a complementary type of transistor to said second MUGFET and a combination of said first MUGFET and said second MUGFET forms a complementary metal oxide semiconductor (CMOS) device.

3. The apparatus according to claim 1, wherein said dummy fins are parallel to, have a same thickness as, and have a smaller length than said fins within said first MUGFET and said second MUGFET.

4. An apparatus comprising:
a first multi-gate, fin-type field effect transistor (MUGFET) adjacent a second MUGFET, wherein each of said first MUGFET and said second MUGFET comprise multiple fins, and wherein each of said fins comprises a channel region, and a source region and a drain region on opposite sides of said channel region;
a source/drain connecting silicide region joining source regions of said first MUGFET to drain regions of said second MUGFET; and
dummy fins lacking said channel region and being positioned within said source/drain connecting silicide region,
wherein said source regions of said first MUGFET, said drain regions of said second MUGFET, and said dummy fins are positioned along a single straight linear path, such that said single straight linear path crosses all of said source regions of said first MUGFET, said drain regions of said second MUGFET, and said dummy fins.

5. The apparatus according to claim 4, wherein said first MUGFET is comprises a complementary type of transistor to said second MUGFET and a combination of said first MUGFET and said second MUGFET forms a complementary metal oxide semiconductor (CMOS) device.

6. The apparatus according to claim 4, wherein said dummy fins are parallel to, have a same thickness as, and have a smaller length than said fins within said first MUGFET and said second MUGFET.
